(19) United States
(12) Patent Application Publication
(10) Pub. No.: US 2025/0185318 A1
(43) Pub. Date: Jun. 5, 2025

(54) SEMICONDUCTOR DEVICE AND SEMICONDUCTOR MODULE

(71) Applicant: FUJI ELECTRIC CO., LTD., Kawasaki-shi (JP)

(72) Inventor: Keiji OKUMURA, Matsumoto-city (JP)

(73) Assignee: FUJI ELECTRIC CO., LTD., Kawasaki-shi (JP)

(21) Appl. No.: 18/934,206

(22) Filed: Oct. 31, 2024

(30) Foreign Application Priority Data
Dec. 1, 2023 (JP) 2023-204279

(51) Int. Cl. H01L 29/06; H01L 21/66; H01L 27/06; H01L 29/423; H01L 29/78

(52) U.S. Cl. CPC H10D 62/127; H01L 22/32; H10D 30/668; H10D 64/519; H10D 84/811

(57) ABSTRACT

A semiconductor device, including: a semiconductor device element provided in a semiconductor substrate and having an insulated gate; a main electrode pad provided at the semiconductor substrate for energizing the semiconductor device element; a first external member bonded to the main electrode pad by a metal; a gate pad provided at the semiconductor substrate via an insulating film; a gate finger, a gate resistor and a measuring pad provided at the semiconductor substrate via the insulating film, the gate finger being electrically connected to a gate electrode of the insulated gate, the gate resistor electrically connecting the gate pad and the gate finger, and the measuring pad being electrically connected to the gate finger for measuring a resistance value of the gate resistor. In a plan view of the semiconductor device, a portion of the main electrode pad is between the gate pad and the measuring pad.

### CROSS REFERENCE TO RELATED APPLICATIONS

This application is based upon and claims the benefit of priority of the prior Japanese Patent Application No. 2023-204279, filed on Dec. 1, 2023, the entire contents of which are incorporated herein by reference.

### BACKGROUND OF THE INVENTION

### 1. Field of the Invention

Embodiments of the disclosure relate to a semiconductor device and a semiconductor module.

### 2. Description of the Related Art

Japanese Laid-Open Patent Publication No. 2020-47675 describes a technique of measuring a value of gate resistance by an electrode pad (hereinafter, measuring pad) for measuring gate resistance values, the value of the gate resistance being determined by internal resistance due to a gate polysilicon (poly-Si) layer connected in series between a gate pad and the measuring pad. Japanese Laid-Open Patent Publication No. 2022-44998 describes a technology in which a plating film for making contact with a probe needle of inspection equipment is provided only on a source pad.

### SUMMARY OF THE INVENTION

According to an embodiment of the present disclosure, a semiconductor device includes: a semiconductor substrate having a main surface; a semiconductor device element provided in the semiconductor substrate at the main surface thereof, the semiconductor device element having an insulated gate with a three-layer structure formed by: a metal film that constitutes a gate electrode, an oxide film, and a portion of the semiconductor substrate; a main electrode pad provided at the main surface of the semiconductor substrate for energizing the semiconductor device element; a first external member bonded to the main electrode pad by a metal; a gate pad provided at the main surface of the semiconductor substrate via an insulating film; a gate finger provided at the main surface of the semiconductor substrate via the insulating film, the gate finger being electrically connected to the gate electrode; a gate resistor provided at the main surface of the semiconductor substrate via the insulating film, the gate resistor electrically connecting the gate pad and the gate finger; and a measuring pad for measuring a resistance value of the gate resistor, the measuring pad being provided at the main surface of the semiconductor substrate via the insulating film and being electrically connected to the gate finger. In a plan view of the semiconductor device, a portion of the main electrode pad is between the gate pad and the measuring pad.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a plan view depicting an example of a layout when a semiconductor chip mounted in a semiconductor module according to a first embodiment is viewed from a front side thereof.

FIG. 2 is a cross-sectional view depicting a structure along cutting line A-A′ in FIG. 1.

FIG. 3 is a cross-sectional view depicting the structure along cutting line A-A′ in FIG. 1.

FIG. 4 is a circuit diagram depicting an equivalent circuit of the semiconductor module according to the first embodiment.

FIG. 5 is a plan view depicting an example of a layout when a semiconductor chip mounted on a semiconductor module according to a second embodiment is viewed from a front side thereof.

FIG. 6 is a plan view depicting an example of a layout when a semiconductor chip mounted in a semiconductor module of a reference example is viewed from a front side thereof.

FIG. 7 is a plan view depicting another example of the layout when a semiconductor chip mounted in the semiconductor module of the reference example is viewed from the front side thereof.

FIG. 8 is a cross-sectional view depicting a structure along cutting line AA-AA′ in FIG. 6 (normal state).

FIG. 9 is a cross-sectional view depicting the structure along cutting line AA-AA′ in FIG. 7 (abnormal state).

FIG. 10 is a circuit diagram depicting an equivalent circuit of the semiconductor module of the reference example.

### DETAILED DESCRIPTION OF THE INVENTION

First, problems associated with the conventional techniques are discussed. In Japanese Laid-Open Patent Publication No. 2020-47675 and Japanese Laid-Open Patent Publication No. 2022-44998, in an assembly process of a semiconductor module, when external-lead wiring such as a wire is soldered to the gate pad, the gate pad and the measuring pad may short-circuit due to wet solder, and the resistance value of the gate resistance may fluctuate. Since there is no means of detecting a semiconductor chip (hereinafter, defective chip) in which the gate pad and the measuring pad have the same potential, a product (semiconductor module) in which a defective chip is mounted is shipped.

An outline of an embodiment of the present disclosure is described. (1) A semiconductor device according to one embodiment of the present disclosure has the following features. A semiconductor device element is provided on a semiconductor substrate and has an insulated gate with a three-layer structure including a metal film, an oxide film, and a semiconductor. A main electrode pad is provided at a first main surface of the semiconductor substrate and energizes the semiconductor device element. A first external member is bonded by a metal to the main electrode pad. A gate pad is provided at a first main surface of the semiconductor substrate via an insulating film. A gate finger, also called a gate runner, is provided at the first main surface of the semiconductor substrate via the insulating film.

A gate electrode constituted by the metal film of the insulated gate is electrically connected to the gate finger. A gate resistor is provided at the first main surface of the semiconductor substrate via the insulating film and electrically connects the gate pad and the gate finger. A measuring pad is provided at the first main surface of the semiconductor substrate via the insulating film and is electrically connected to the gate finger. The measuring pad is used to set a resistance value of the gate resistor. In a plan view, a portion of the main electrode pad intervenes between the gate pad and the measuring pad.

According to the disclosure described, even when the gate pad and the measuring pad short-circuit due to adhesion of conductive foreign matter, the gate pad and the main electrode pad short-circuit due to the adhered matter and short-circuit of the gate pad and the measuring pad may be detected.

(2) Further, in the semiconductor device according to the present disclosure, in (1) above, a second external member may be bonded by a metal to the gate pad.

According to the disclosure above, even when the gate pad and the measuring pad short-circuit during bonding of the second external member to the gate pad, the gate pad and the main electrode pad are short-circuited by the bonding material of the second external member and short-circuit of the gate pad and the measuring pad may be detected.

(3) Further, in the semiconductor device according to the present disclosure, in (1) or (2) above, in the plan view, a surface area of a first metal bonding layer bonding the main electrode pad and the first external member may be larger than an opening surface area of the main electrode pad.

According to the disclosure above, short-circuit of the gate pad and the main electrode pad may be induced when conductive foreign matter is adhered or during bonding to the gate pad by a metal.

(4) Further, in the semiconductor device according to the present disclosure, in any one of (1) to (3) above, the passivation film covers the first main surface of the semiconductor substrate. The main electrode pad is exposed in a first opening of the passivation film. A first metal bonding layer bonding the main electrode pad and the first external member may fill the first opening and extend on the surface of the passivation film.

According to the disclosure above, short-circuit of the gate pad and the main electrode pad may be induced when conductive foreign matter is adhered or during bonding to the gate pad by a metal.

(5) Further, in the semiconductor device according to the present disclosure, in any one of (1) to (4) above, in the plan view, a surface area of a second metal bonding layer bonding the gate pad and the second external member may be larger than an opening surface area of the gate pad.

According to the disclosure above, short-circuit of the gate pad and the main electrode pad may be induced when the second external member is bonded to the gate pad.

(6) Further, in the semiconductor device according to the present disclosure, in any one of (1) to (5) above, a passivation film covers the first main surface of the semiconductor substrate. The gate pad is exposed in a second opening of the passivation film. The second metal bonding layer bonding the gate pad and the second external member may fill the second opening and extend on the surface of the passivation film.

According to the disclosure above, short-circuit of the gate pad and the main electrode pad may be induced when the second external member is bonded to the gate pad.

(7) Further, in the semiconductor device according to the present disclosure, in any one of (1) to (6) above, the first metal bonding layer may be formed by a solder material or a metal sintering material.

According to the disclosure above, short-circuit of the gate pad and the main electrode pad may be induced when conductive foreign matter is adhered or during bonding to the gate pad by a metal.

(8) Further, in the semiconductor device according to the present disclosure, in any one of (1) to (7) above, the second metal bonding layer may be formed by a solder material or a metal sintering material.

According to the disclosure above, short-circuit of the gate pad and the main electrode pad may be induced during bonding of the second external member to the gate pad.

(9) Further, in the semiconductor device according to the present disclosure, in any one of (1) to (8) above, the first metal bonding layer is constituted by a solder material. The main electrode pad may be bonded to the first metal bonding layer via a plating film.

According to the disclosure above, wettability of the first metal bonding layer may be enhanced.

(10) Further, in the semiconductor device according to the present disclosure, in any one of (1) to (9) above, the second metal bonding layer is constituted by a solder material. The gate pad may be bonded to the second metal bonding layer via a plating film.

According to the disclosure above, wettability of the second metal bonding layer may be enhanced.

(11) A semiconductor module according to an embodiment of the disclosure is a semiconductor module in which the semiconductor device of any one of (1) to (10) above is mounted; the semiconductor module has the following features. The semiconductor device element is mounted in plural. The semiconductor device elements are connected in parallel. The first external member is bonded by a metal to each main electrode pad of the semiconductor device elements.

According to the disclosure above, a semiconductor device element in which the gate pad and the measuring pad are short-circuited may be detected from the semiconductor device elements connected in parallel.

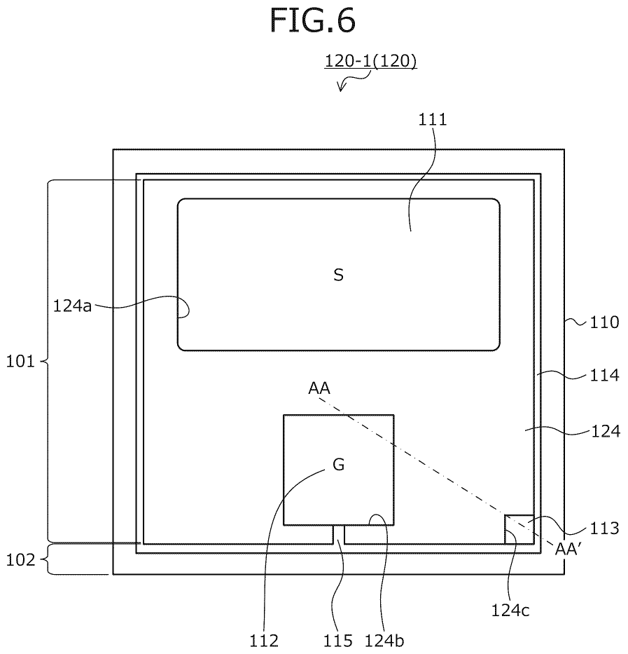

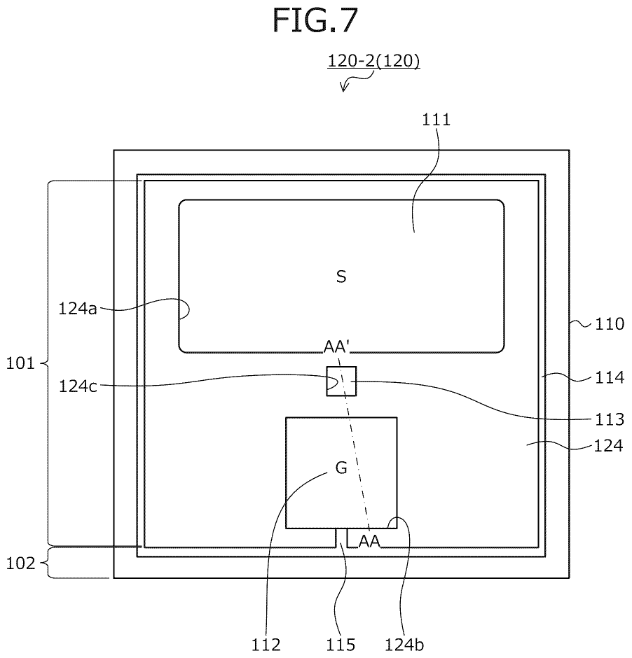

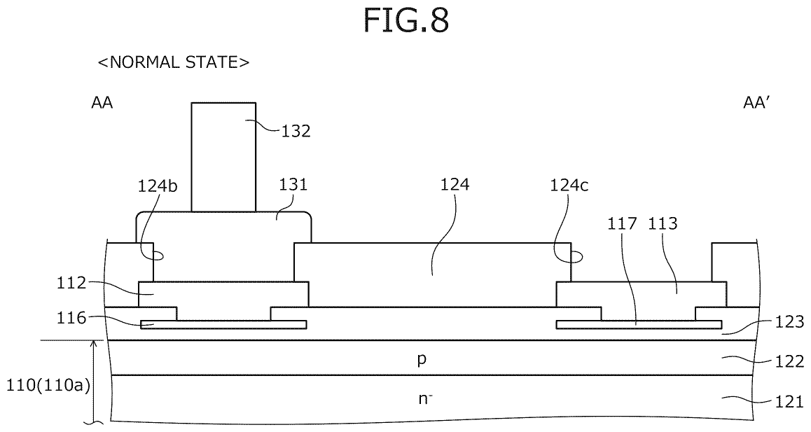

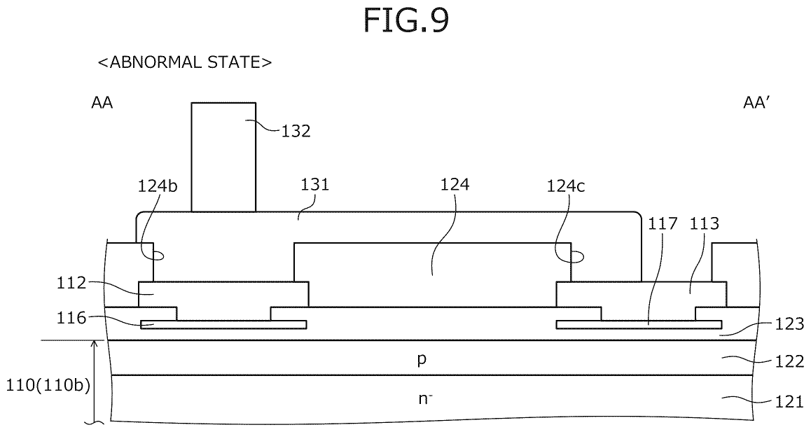

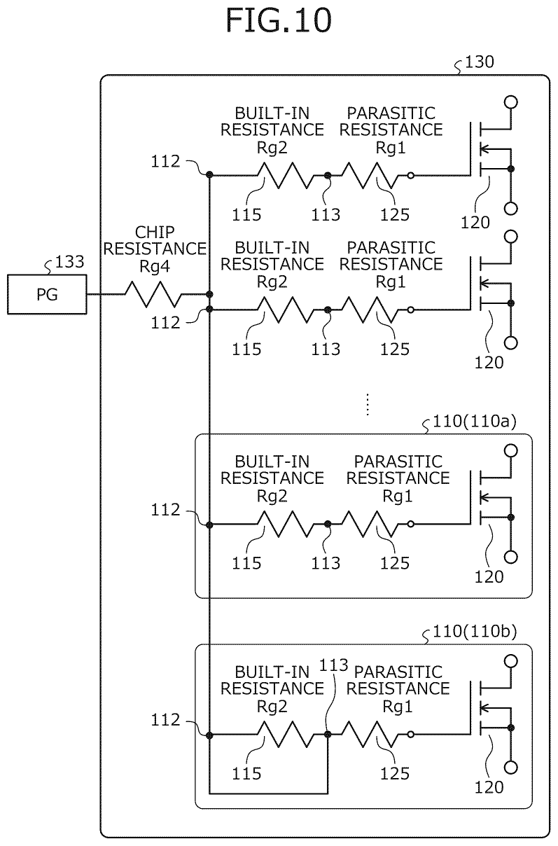

Findings underlying the present disclosure are discussed. First, a semiconductor module of a reference example is described. FIGS. 6 and 7 are plan views depicting examples of layouts when a semiconductor chip mounted in the semiconductor module of the reference example is viewed from a front side thereof. FIG. 6 is FIG. 7 of Japanese Laid-Open Patent Publication No. 2020-47675. FIGS. 8 and 9 are cross-sectional views depicting the structure along cutting line AA-AA′ in FIGS. 6 and 7. FIGS. 8 and 9 respectively depict normal (conforming chip 110a) and abnormal (defective chip 110b) states after external-lead wiring 132 is soldered to a gate pad 112 of a semiconductor chip 110 mounted in a semiconductor module 130 of the reference example (refer to FIG. 10). FIG. 10 is a circuit diagram depicting an equivalent circuit of the semiconductor module of the reference example.

A semiconductor device 120-1 depicted in FIG. 6 is a vertical metal oxide semiconductor field effect transistor (MOSFET) 120 having an insulated gate with a three-layer metal-oxide-semiconductor structure and having a source pad 111, the gate pad 112, and a measuring pad 113 on a front surface of the semiconductor chip 110, in an active region 101, the semiconductor device 120-1 being mounted in the semiconductor module 130 of the reference example depicted in FIG. 10. The active region 101 has a substantially rectangular shape in a plan view and is disposed in substantially a center of the semiconductor chip 110. An edge terminating region 102 is between the active region 101 and an end of the semiconductor chip 110. The edge terminating region 102 surrounds a periphery of the active region 101 in a plan view.

A source electrode of the MOSFET 120 is provided on the front surface of the semiconductor chip 110. A passivation film 124 has an opening 124a with a substantially rectangular shape in a plan view and a portion of the source electrode exposed in the opening 124a functions as the source pad 111. The source pad 111, the gate pad 112, and the measuring pad 113 are exposed, respectively, by different openings 124a, 124b, 124c of the passivation film 124. The gate pad 112 has a substantially rectangular shape in a plan view and is disposed near a boundary between the active region 101 and the edge terminating region 102. The measuring pad 113 has a substantially rectangular shape in a plan view and is disposed apart from the source pad 111 and the gate pad 112, in a corner portion of the active region 101, the corner portion being one of four corner portions (vertices) of the active region 101 and closest to the gate pad 112 among the four corner portions.

The measuring pad 113 is connected to a gate finger 114. The gate finger 114 is provided on the front surface of the semiconductor chip 110 via a field oxide film 123 and in the edge terminating region 102, the gate finger 114 surrounds the periphery of the active region 101 in substantially a rectangular shape in a plan view. The gate finger 114 is electrically connected to the gate pad 112 via a gate resistor 115. Gate electrodes 125 of all cells (functional units of a device) of the MOSFET 120, provided in the active region 101 are connected to the gate finger 114 (refer to FIG. 10). Built-in resistance Rg2 due to the gate resistor 115 containing a polysilicon and parasitic resistance Rg1 due to the gate electrodes 125 containing a polysilicon are connected in series by the gate finger 114.

Combined resistance of the built-in resistance Rg2 due to the gate resistor 115 and the parasitic resistance Rg1 due to the gate electrodes 125 is an overall gate resistance Rg3 of the MOSFET 120. The resistance value of the built-in resistance Rg2 due to the gate resistor 115 is set to be higher than a resistance value of the parasitic resistance Rg1 due to the gate electrodes 125, so that a resistance value of the overall gate resistance Rg3 of the MOSFET 120 is determined by a resistance value of the built-in resistance Rg2 due to the gate resistor 115. The measuring pad 113 is connected to the gate finger 114, whereby the built-in resistance Rg2 due to the gate resistor 115 is connected in series between the gate pad 112 and the measuring pad 113 and a resistance value of the built-in resistance Rg2 may be measured by the measuring pad 113.

However, the greater is the distance between the measuring pad 113 and the gate pad 112, the longer a gate polysilicon wiring layer configuring the gate finger 114 is drawn between the measuring pad 113 and the gate pad 112. Therefore, a resistance value of the gate polysilicon wiring layer configuring the gate finger 114 cannot be disregarded and is added to the resistance value measured by the measuring pad 113, whereby the resistance value of the overall gate resistance Rg3 of the MOSFET 120 increases. Further, during switching of the MOSFET 120, a potential of the field oxide film 123 directly beneath the gate finger 114 is raised by a displacement current flowing through the semiconductor chip 110 directly beneath (n⁺-type drain region side) the gate finger 114 and dielectric breakdown may occur at this location.

A path of the displacement current flowing directly beneath the gate finger 114 increases by the long length that the gate finger 114 is drawn between the measuring pad 113 and the gate pad 112 and thus, dielectric breakdown directly beneath the gate finger 114 tends to occur. Further, the displacement current flows directly beneath the gate finger 114, in a p-type region 122 between the front surface of the semiconductor chip 110 and an n⁻-type drift region 121 and is lead out to the source electrode. When silicon carbide (SiC) is used as a semiconductor material of the semiconductor chip 110, sheet resistance of a p-type SiC is high and thus, the potential of the field oxide film 123 directly beneath the gate finger 114 is easily raised by the displacement current flowing in the p-type region 122 directly beneath the gate finger 114 and is particularly remarkable under low temperature environments.

When the MOSFET 120 is switched at high speeds, high voltage (=current value of displacement current flowing through the p-type region 122×the sheet resistance value of the p-type region 122) is applied to the semiconductor chip 110 with a steep dV/dt (rate of change of voltage over time) and thus, dielectric breakdown directly beneath the gate finger 114 tends to occur. A semiconductor device 120-2 depicted in FIG. 7 differs from the semiconductor device 120-1 depicted in FIG. 6 in that the semiconductor device 120-2 shortens the distance between the gate pad 112 and the measuring pad 113 and suppresses dielectric breakdown directly beneath the gate finger 114. The measuring pad 113 of the semiconductor device 120-2 is disposed between the source pad 111 and the gate pad 112, at a position apart from the source pad 111 and the gate pad 112 but relatively closer to the gate pad 112.

A semiconductor module 130 depicted in FIG. 10 is a MOSFET module in which the semiconductor chip 110 is one of multiple chips each having the same structure as that depicted in FIG. 6 or FIG. 7 and the MOSFETs 120 fabricated in the chips are connected in parallel. The gate pads 112 of the semiconductor chips 110 are connected in parallel by the external-lead wiring 132 (refer to FIGS. 8 and 9) via a chip resistance Rg4 of the semiconductor chip 110 itself and are electrically connected to a protective ground (PG) 133 of the semiconductor module 130. In each of the semiconductor chips 110, the parasitic resistance Rg1 due to the gate electrodes 125 and the built-in resistance Rg2 due to the gate resistor 115 are connected in series between the PG 133 and the gate electrodes 125 of the MOSFET 120.

Among the semiconductor chips 110, variation of the parasitic resistance Rg1 due to the gate electrodes 125 is large. Thus, the resistance value of the built-in resistance Rg2 due to the gate resistor 115 attached to the semiconductor chips 110 is adjusted, thereby controlling the resistance value of the gate resistance Rg3 of the semiconductor chip 110, the resistance value of the gate resistance Rg3 being determined by the resistance value of the built-in resistance Rg2. Based on the resistance value of the built-in resistance Rg2 due to the gate resistor 115 and measured using the measuring pad 113, the semiconductor chips 110 are sorted and only the semiconductor chips 110 in which a resistance value of the gate resistance Rg3 is within a predetermined range are mounted in the semiconductor module 130. As described, switching variation among the multiple semiconductor chips 110 connected in parallel in the semiconductor module 130 is reduced.

However, during assembly of the semiconductor module 130, the measuring pad 113 of the semiconductor chips 110 is in an exposed state. Thus, when the distance between the gate pad 112 and the measuring pad 113 is shortened like the semiconductor device 120-2 in FIG. 7 and the external-lead wiring 132 such as a wire is soldered to the gate pad 112; on the gate pad 112 and the measuring pad 113, solder spreads wet from the gate pad 112 to the measuring pad 113 and the gate pad 112; and the measuring pad 113 may short-circuit via a solder layer 131 (FIG. 9). Even when the distance between the gate pad 112 and the measuring pad 113 is sufficiently long like the semiconductor device 120-1 in FIG. 6, the gate pad 112 and the measuring pad 113 may short-circuit due to adhesion of conductive foreign matter (not depicted).

When the gate pad 112 and the measuring pad 113 short-circuit, the resistance value of the built-in resistance Rg2 due to the gate resistor 115 becomes zero, the resistance value of the gate resistance Rg3 varies, and the affected semiconductor chip 110 (malfunctions) turns on sooner than the other semiconductor chips 110 (the conforming chips 110a: FIG. 8) in the semiconductor module 130, becoming a defective chip 110b. Since there is no means of detecting a defective chip 110b having the same potential as the potential of the gate pad 112 and the measuring pad 113, a product (the semiconductor module 130) in which the defective chip 110b is mounted is shipped. On the other hand, when the distance between the gate pad 112 and the measuring pad 113 is increased to prevent short-circuits, as described above, the resistance value of the gate resistance Rg3 increases and dielectric breakdown due to displacement current occurs.

In the present embodiment, preventing the shipping of a defective chip is one problem to be solved.

Embodiments of a semiconductor device and a semiconductor module according to the present disclosure are described in detail with reference to the accompanying drawings. In the present description and accompanying drawings, layers and regions prefixed with n or p mean that majority carriers are electrons or holes. Additionally, +or − appended to n or p means that the impurity concentration is higher or lower, respectively, than layers and regions without +or −. In the description of the embodiments below and the accompanying drawings, main portions that are identical are given the same reference numerals and are not repeatedly described.

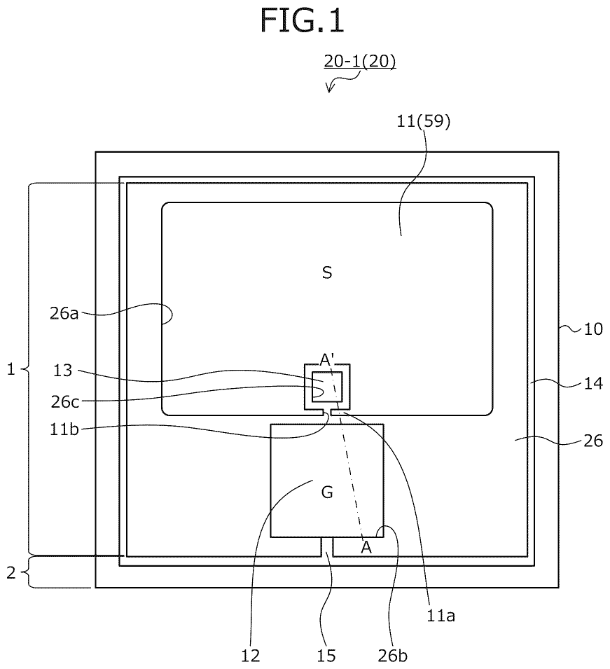

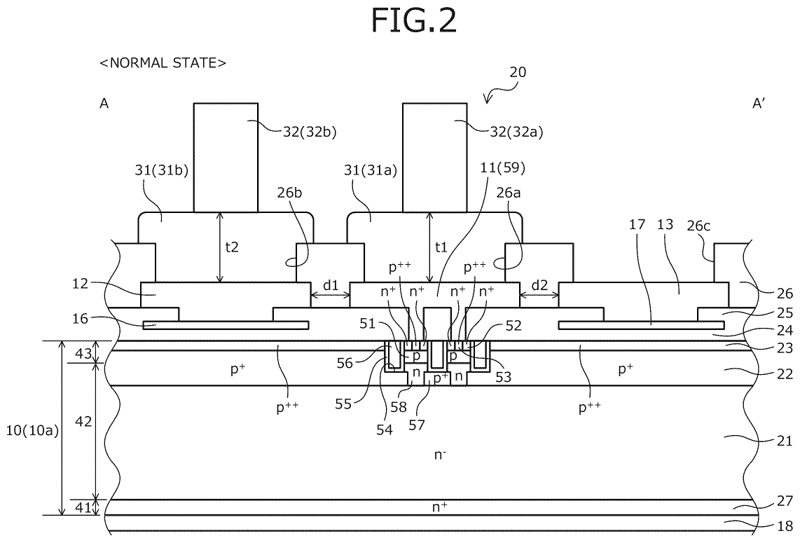

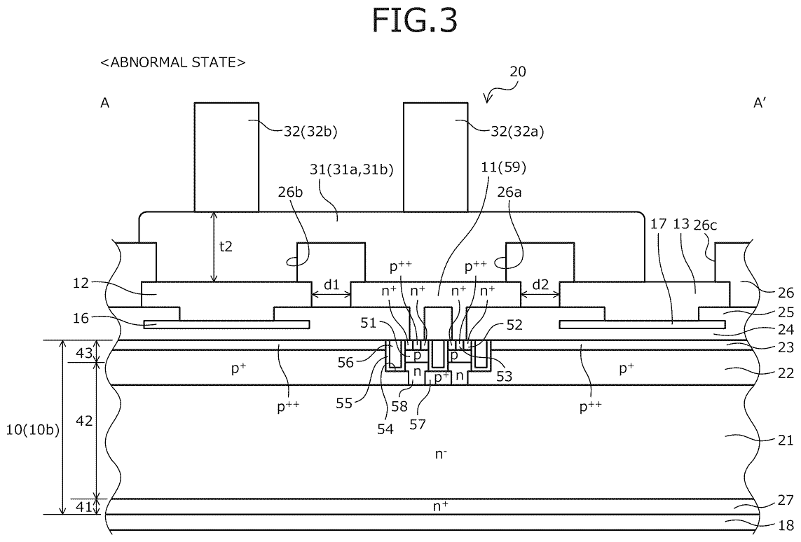

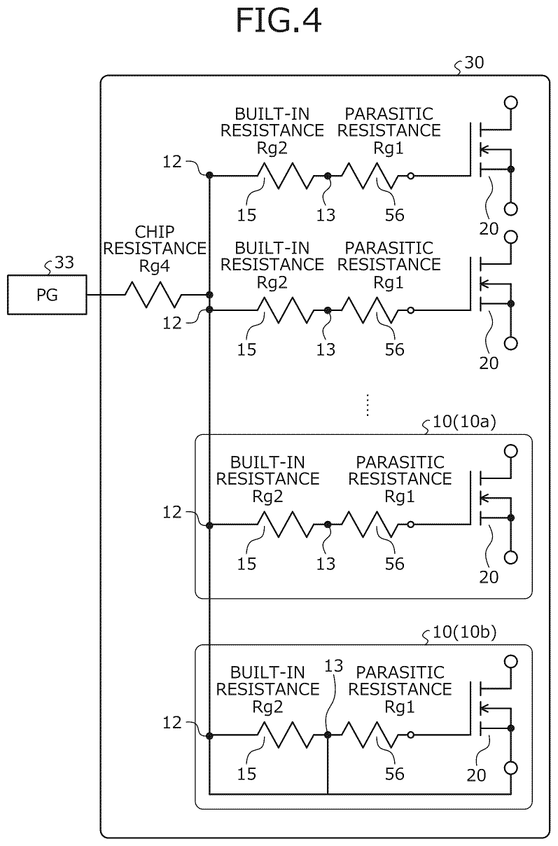

A semiconductor device and a semiconductor module according to a first embodiment solving the problems above are described. FIG. 1 is a plan view depicting an example of a layout when a semiconductor chip mounted in the semiconductor module according to the first embodiment is viewed from a front side thereof. FIGS. 2 and 3 are cross-sectional views depicting the structure along cutting line A-A′ in FIG. 1. FIGS. 2 and 3 depict, respectively, a state of a measuring pad 13 in a normal state (conforming chip 10a) and a state of the measuring pad 13 in an abnormal state (defective chip 10b) after external-lead wiring 32 is soldered to a gate pad 12 of a semiconductor chip 10 mounted in the semiconductor module 30 (refer to FIG. 4). FIG. 4 is a circuit diagram depicting an equivalent circuit of the semiconductor module according to the first embodiment.

A semiconductor device 20-1 according to the first embodiment depicted in FIGS. 1 to 3 is a vertical MOSFET (semiconductor device element) 20 having, on a front surface of the semiconductor chip 10, a source pad (main electrode pad) 11, the gate pad 12, and the measuring pad 13, in an active region 1, the semiconductor device 20-1 being mounted in the semiconductor module 30 according to the first embodiment depicted in FIG. 4. The active region 1 has a substantially rectangular shape in a plan view and is disposed in substantially a center of the semiconductor chip 10. The active region 1 has an operating region (hereinafter, active-region operating region) that is a region through which a main current flows when the MOSFET 20 is in an on-state and that occupies a majority of the active region 1. In the active-region operating region, multiple cells (functional units of a device) of the MOSFET 20 are disposed adjacent to one another, each of the cells having the same structure.

An edge terminating region 2 is between the active region 1 and the semiconductor chip 10. The edge terminating region 2 surrounds a periphery of the active region 1 in a plan view. The edge terminating region 2 has a function of mitigating electric field of a front side of the semiconductor chip 10 and sustaining a breakdown voltage. The breakdown voltage is a voltage limit at which no malfunction or destruction of a device element occurs. In the edge terminating region 2, for example, a voltage withstanding structure (not depicted) such as a junction termination extension (JTE) structure or a field limiting ring (FLR) structure is disposed.

A source electrode 59 (refer to FIGS. 2 and 3) of the MOSFET 20 is provided on the front surface of the semiconductor chip 10 and covers substantially an entire area of the active-region operating region. A portion of the source electrode 59 exposed in an opening (first opening) 26a of a passivation film 26 functions as a source pad 11. The source pad 11, the gate pad 12, and the measuring pad 13 are exposed, respectively, in different openings 26a, 26b, 26c of the passivation film 26 and are disposed apart from one another. The source pad 11, the gate pad 12, and the measuring pad 13 are electrically insulated by an interlayer insulating film 25 and the passivation film 26.

As depicted in FIG. 1, in a plan view, the source pad 11 has a substantially rectangular shape in which a portion is recessed so as to surround a periphery of the measuring pad 13, the recessed portion surrounding nearly the entire periphery of the measuring pad 13 in a substantially rectangular shape having an open portion 11b. In the active region 1, directly beneath the gate pad 12, the measuring pad 13, and a gate resistor 15, is an active-region non-operating region (region excluding the active-region operating region) that does not function as the MOSFET 20 and that is free of cells of the MOSFET 20. The gate pad 12 has a substantially rectangular shape in a plan view and is disposed near an outer periphery of the active region 1. The measuring pad 13 has a substantially rectangular shape in a plan view and is disposed between the source pad 11 and the gate pad 12.

Nearly the entire periphery of the measuring pad 13 faces the source pad 11 in a direction parallel to the front surface of the semiconductor chip 10 with only the passivation film 26 intervening therebetween. A portion 11a of the source pad 11 excluding the open portion 11b of the source pad 11 intervenes between the gate pad 12 and the measuring pad 13. At the open portion 11b of the source pad 11, the measuring pad 13 faces the gate pad 12 in a direction parallel to the front surface of the semiconductor chip 10, via the passivation film 26. The measuring pad 13, at a non-depicted portion thereof, is electrically connected to a gate polysilicon (poly-Si) wiring layer that constitutes a gate finger 14.

In other words, the source pad 11 is disposed so as to overlap a linear path in a direction from the gate pad 12 to the measuring pad 13 when viewed from the front surface of the semiconductor chip 10 (in a plan view). The gate pad 12 has a relatively small area and when the external-lead wiring 32b (refer to FIGS. 2 and 3) is soldered to the gate pad 12, adjusting the amount of solder applied on the gate pad 12 is difficult. Solder material applied on the gate pad 12 may flow out on the surface of the passivation film 26 and wet and spread toward the measuring pad 13 and thus, it suffices for a portion of the source pad 11 to be disposed on the path that the solder material wets and spreads on in a direction from the gate pad 12 to the measuring pad 13.

The gate finger 14 is provided on the front surface of the semiconductor chip 10, in the edge terminating region 2 via a field oxide film 24. The gate finger 14 is formed by the gate polysilicon wiring layer and a gate metal wiring layer stacked in the order stated. The gate polysilicon wiring layer configuring the gate finger 14 is provided at a same level as the gate resistor 15 and later-described gate polysilicon layers 16, 17 (refer to FIGS. 2 and 3) and surrounds the periphery of the active region 1 in a substantially rectangular shape in a plan view. Further, the gate polysilicon wiring layer configuring the gate finger 14 is electrically connected to the gate pad 12 via the gate resistor 15.

Gate electrodes 56 of all the cells of the MOSFET 20 are connected to the gate polysilicon wiring layer configuring the gate finger 14. The gate finger 14 connects the built-in resistance Rg2 due to the gate resistor 15 containing a polysilicon and the parasitic resistance Rg1 due to the gate electrodes 56 containing a polysilicon in series. Further, the gate polysilicon wiring layer configuring the gate finger 14 is drawn inside the active region 1, passes through the open portion 11b of the source pad 11, extends toward the measuring pad 13 (not depicted), and is connected to the measuring pad 13 and the gate polysilicon layer 17 directly beneath the measuring pad 13.

The gate polysilicon wiring layer configuring the gate polysilicon wiring layer is covered by the interlayer insulating film 25. The gate metal wiring layer configuring the gate finger 14 is provided at a same level as the source pad 11, the gate pad 12, and the measuring pad 13, surrounds the periphery of the active region 1 in a substantially rectangular shape in a plan view, and is connected to the gate polysilicon wiring layer directly below, via a contact hole in the interlayer insulating film 25. The gate resistor 15 is a gate polysilicon layer provided on the front surface of the semiconductor chip 10 via the field oxide film 24, in the active-region non-operating region, the gate resistor 15 being disposed between the gate pad 12 and the gate finger 14.

A first end of the gate resistor 15 is connected to the gate polysilicon layer 16 directly beneath the gate pad 12. A second end of the gate resistor 15 is connected to the gate polysilicon wiring layer configuring the gate finger 14. A combined resistance of the built-in resistance Rg2 due to the gate resistor 15 and the parasitic resistance Rg1 due to the gate electrodes 56 is the overall gate resistance Rg3 of the MOSFET 20. The resistance value of the built-in resistance Rg2 due to the gate resistor 15 is set to be higher than the resistance value of the parasitic resistance Rg1 due to the gate electrodes 56 so that the resistance value of the overall gate resistance Rg3 of the MOSFET 20 is determined by the resistance value of the built-in resistance Rg2 due to the gate resistor 15.

The measuring pad 13 is connected to the gate finger 14, whereby the built-in resistance Rg2 due to the gate resistor 15 is connected in series between the gate pad 12 and the measuring pad 13 and the resistance value of the built-in resistance Rg2 may be measured by the measuring pad 13. A distance between the gate pad 12 and the measuring pad 13 is relatively short and thus, the length of the gate finger 14 (the gate polysilicon wiring layer) drawn between the gate pad 12 and the measuring pad 13 is relatively short. As a result, the resistance value of the gate polysilicon wiring layer configuring the gate finger 14 may be disregarded and is not added to the measured resistance value obtained by the measuring pad 13.

A cross-section of the structure of the semiconductor device 20-1 is described taking an instance in which the semiconductor material of the semiconductor chip 10 is SiC. As depicted in FIGS. 2 and 3, the semiconductor chip 10 is a semiconductor substrate in which, for example, on a front surface of an n⁺-type starting substrate 41 containing, SiC as a semiconductor material, epitaxial layers 42, 43 constituting respectively, an n⁻-type drift region 21 and a p-type base region 51 are sequentially stacked in the order stated. The n⁺-type starting substrate 41 constitutes an n⁺-type drain region 27. The semiconductor chip 10 has, as a front surface, a first main surface that is a surface of the p-type epitaxial layer 43 and has, as a back surface, a second main surface that is a surface of the n⁺-type starting substrate 41.

In the active-region operating region, in a front side of the semiconductor chip 10, a device structure (herein, a trench gate structure) of the MOSFET 20 is provided. The trench gate structure is configured by the p-type base region 51, n⁺-type source regions 52, p⁺⁺-type contact regions 53, trenches 54, gate insulating films 55, and the gate electrodes 56. A portion of the p-type epitaxial layer 43 excluding the n⁺-type source regions 52, the p⁺⁺-type contact regions 53, a later-described p⁺-type outer peripheral region 22, and a later-described p⁺⁺-type outer peripheral region 23, constitutes the p-type base region 51. The p-type base region 51 is provided between the front surface of the semiconductor chip 10 and the n⁻-type drift region 21.

The n⁺-type source regions 52 and the p⁺⁺-type contact regions 53 are diffused regions formed by ion implantation in the p-type epitaxial layer 43. The n⁺-type source regions 52 and the p⁺⁺-type contact regions 53 are each selectively provided between the front surface of the semiconductor chip 10 and the p-type base region 51 and in contact with the p-type base region 51. The n⁺-type source regions 52 and the p⁺⁺-type contact regions 53 are in contact with the source electrode 59 at the front surface of the semiconductor chip 10. The p⁺⁺-type contact regions 53 may be omitted. In this instance, instead of the p⁺⁺-type contact regions 53, the p-type base region 51 reaches the front surface of the semiconductor chip 10.

The trenches 54 penetrate through the n⁺-type source regions 52 and the p-type base region 51 from the front surface of the semiconductor chip 10 in a depth direction and terminate in later-described n-type current spreading regions 58. The trenches 54, for example, are provided adjacent to one another in a striped pattern parallel to the front surface of the semiconductor chip 10. Of the trenches 54, ones closest to the active-region non-operating region each has a sidewall facing the active-region non-operating region and at the sidewall, penetrates through the p⁺⁺-type outer peripheral region 23 and the p⁺-type outer peripheral region 22 from the front surface of the semiconductor chip 10 in the depth direction and terminates in the p⁺-type outer peripheral region 22. In the trenches 54, the gate insulating films 55 are provided and the gate electrodes 56 are provided on the gate insulating films 55, respectively.

Between the p-type base region 51 and the n⁻-type drift region 21, at positions closer to the n⁺-type drain region 27 than are bottoms of the trenches 54, p⁺-type regions 57 and the n-type current spreading regions 58 are each selectively provided. The p⁺-type regions 57 and the n-type current spreading regions 58 are diffused regions formed in the n⁻-type epitaxial layer 42 by ion implantation. A portion of the n⁻-type epitaxial layer 42 excluding the p⁺-type regions 57, the n-type current spreading regions 58, and the later-described p⁺-type outer peripheral region 22, constitutes the n⁻-type drift region 21. The p⁺-type regions 57, at a non-depicted portion, are fixed to a potential of the source electrode 59.

The p⁺-type regions 57 deplete (or cause the n-type current spreading regions 58 to deplete or both) when the MOSFET 20 is off and thus, have a function of mitigating electric field near the bottoms of the trenches 54. The p⁺-type regions 57 are provided apart from the p-type base region 51 and face the bottoms of the trenches 54 in the depth direction. The p⁺-type regions 57 may be in contact with the gate insulating films 55 at the bottoms of the trenches 54 or may be apart from the trenches 54. The p⁺-type regions 57 each has a bottom surface (surface facing the n⁺-type drain region 27) and may be in contact with the n⁻-type drift region 21 at the bottom surface and a periphery of each may be bordered by the n-type current spreading regions 58.

The n-type current spreading regions 58 constitute a so-called current spreading layer (CSL) that reduces carrier spreading resistance. The n-type current spreading regions 58 are adjacent to the p⁺-type regions 57 and the trenches 54 in a direction parallel to the front surface of the semiconductor chip 10, each of the n-type current spreading regions 58 has a top surface (surface facing the n⁺-type source regions 52) and a bottom surface opposite thereto, is in contact with the p-type base region 51 at the top surface and is in contact with the n⁻-type drift region 21 at the bottom surface. The n-type current spreading regions 58 may be omitted. In this instance, instead of the n-type current spreading regions 58, the n⁻-type drift region 21 reaches the p-type base region 51 and reaches the trenches 54, between the p-type base region 51 and the p⁺-type regions 57.

The interlayer insulating film 25 is provided in an entire area of the front surface of the semiconductor chip 10 and covers all the gate electrodes 56. The source electrode 59 is in ohmic contact with the front surface of the semiconductor chip 10 via a contact hole in the interlayer insulating film 25 and is electrically connected to the p-type base region 51, the n⁺-type source regions 52, and the p⁺⁺-type contact regions 53. A drain electrode 18 is provided in an entire area of the back surface (back surface of the n⁺-type starting substrate 41) of the semiconductor chip 10. The drain electrode 18 is in ohmic contact with the back surface of the semiconductor chip 10 and is electrically connected to the n⁺-type drain region 27 (the n⁺-type starting substrate 41).

In the active-region non-operating region, in an entire area between the front surface of the semiconductor chip 10 and the n⁻-type drift region 21, the p⁺-type outer peripheral region 22 is provided in contact with the n⁻-type drift region 21. The p⁺-type outer peripheral region 22 is a diffused region formed in the epitaxial layers 42, 43 by ion implantation. The p⁺-type outer peripheral region 22 surrounds a periphery of the active-region operating region. The p⁺-type outer peripheral region 22 may extend toward the active-region operating region and of the trenches 54, reach the sidewalls of the ones closest to the active-region non-operating region, and be in contact with the p⁺-type regions 57 directly beneath the trenches 54 closest to the active-region non-operating region, among the trenches 54. A depth of the bottom surface of the p⁺-type outer peripheral region 22 may be substantially a same depth as a depth of the bottom surfaces of the p⁺-type regions 57.

In an entire area between the front surface of the semiconductor chip 10 and the p⁺-type outer peripheral region 22, the p⁺⁺-type outer peripheral region 23 is provided in contact with the p⁺-type outer peripheral region 22. The p⁺⁺-type outer peripheral region 23 is a diffused region formed in the p-type epitaxial layer 43 by ion implantation. The p⁺⁺-type outer peripheral region 23 is covered by the field oxide film 24. The p⁺⁺-type outer peripheral region 23 surrounds the periphery of the active-region operating region. The p⁺⁺-type outer peripheral region 23 may be formed concurrently with the p⁺⁺-type contact regions 53. The p⁺⁺-type outer peripheral region 23 may be omitted. In this instance, instead of the p⁺⁺-type outer peripheral region 23, the p⁺-type outer peripheral region 22 reaches the front surface of the semiconductor chip 10.

The p⁺-type outer peripheral region 22 and the p⁺⁺-type outer peripheral region 23, at non-depicted portions, are electrically connected to the source electrode 59 and have a function of leading out holes to the source electrode 59 when the MOSFET 20 turns off, the holes that accumulate in the n⁻-type drift region 21 in the edge terminating region 2 due to switching of the MOSFET 20, etc. In the active-region non-operating region, an entire area of the front surface of the semiconductor chip 10 is covered by an insulating layer having a stacked structure in which the field oxide film 24 and the interlayer insulating film 25 are sequentially stacked in the order stated. The gate resistor 15 (refer to FIG. 1) and the gate polysilicon layers 16, 17 are provided between the field oxide film 24 and the interlayer insulating film 25.

The gate polysilicon layers 16, 17 are disposed apart from each other and are exposed, respectively, by different contact holes of the interlayer insulating film 25. The gate polysilicon layers 16, 17 may be partially connected and the gate pad 12 and the measuring pad 13 are provided on the gate polysilicon layers 16, 17, in the contact holes of the interlayer insulating film 25, respectively. The gate pad 12 and the measuring pad 13 are provided at a same level as the source electrode 59 (the source pad 11). The source pad 11, the gate pad 12, and the measuring pad 13 terminate on the interlayer insulating film 25, apart from one another.

The passivation film 26 covers substantially an entire area of an uppermost surface (i.e., the surface of the interlayer insulating film 25) of the front surface of the semiconductor chip 10 and is a surface protecting film that protects the front surface of the semiconductor chip 10. In the openings 26a to 26c of the passivation film 26, the source pad 11 (the source electrode 59), the gate pad 12, and the measuring pad 13 are exposed, respectively. The surfaces of the gate pad 12, the measuring pad 13, the gate finger 14, the gate resistor 15, and the gate polysilicon layers 16, 17 face the p⁺⁺-type outer peripheral region 23 and the p⁺-type outer peripheral region 22, via the field oxide film 24, in the depth direction.

The portion 11a of the source pad 11 intervening between the gate pad 12 and the measuring pad 13 short-circuits with the gate pad 12 when the gate pad 12 and the measuring pad 13 short-circuit, and even when the MOSFETs 20 of the semiconductor chips 10 are connected in parallel, short-circuit of the gate pad 12 and the measuring pad 13 may be detected. The source pad 11 has a relatively large surface area and at a location relatively far from the gate pad 12 and the measuring pad 13, a solder material is applied, thereby soldering a later described external-lead wiring (first external member) 32a. Thus, there is a low possibility that the solder material wets and spreads from on the source pad 11 to the gate pad 12 and to the measuring pad 13.

Between the gate pad 12 and the measuring pad 13, preferably, a distance d1 between the gate pad 12 and the source pad 11 and a distance d2 between the measuring pad 13 and the source pad 11 may be substantially the same. Between the gate pad 12 and the measuring pad 13, electrical variation points decrease the more evenly spaced the gate pad 12, the source pad 11, and the measuring pad 13 are disposed and thus, detection of abnormal points other than short-circuit of the gate pad 12 and the measuring pad 13 is facilitated. The distance d1 between the gate pad 12 and the source pad 11 may be shorter than the distance d2 between the measuring pad 13 and the source pad 11.

When the distance d1 between the gate pad 12 and the source pad 11 is shorter, during soldering of external-lead wiring (second external member) 32b to the gate pad 12, short-circuit of the gate pad 12 and the source pad 11 may be induced by solder material flowing out on the surface of the passivation film 26 from on the gate pad 12. Thus, detection sensitivity with respect to the semiconductor chip 10 (hereinafter, the defective chip 10b) in which the gate pad 12 and the measuring pad 13 have short-circuited is enhanced. Further, the distance d2 between the measuring pad 13 and the source pad 11 is increased, whereby short-circuit of the source pad 11 and the measuring pad 13 is inhibited.

The measuring pad 13 is apart from the gate pad 12 by a distance corresponding to the resistance value of the built-in resistance Rg2 set in the gate resistor 15 connected in series between the gate pad 12 and the measuring pad 1. Further, preferably, the measuring pad 13 may be apart from the gate pad 12 by a distance not more than ½ of the width of one side of the semiconductor chip 10. In other words, when the gate pad 12 is disposed near a center of one predetermined side of an outer periphery of the semiconductor chip 10, the measuring pad 13 is disposed between the center of the one predetermined side of the outer periphery of the semiconductor chip 10, where the gate pad 12 is disposed, and both ends (corner portions (vertices) of the semiconductor chip 10) of the one predetermined side.

In particular, preferably, the measuring pad 13, for example, may be apart from the gate pad 12 by a distance in a range of about 50 μm to 300 μm. The distance between the gate pad 12 and the measuring pad 13 is relatively short and thus, during switching of the MOSFET 20, raising of the potential of the field oxide film 24 due displacement current flowing through the semiconductor chip 10 directly beneath the gate finger 14 may be suppressed. Further, preferably, the measuring pad 13 may be apart from the gate pad 12 by a distance at least equal to thicknesses t1, t2 (about 100 μm) of later-described solder layers 31. As a result, short-circuit of the gate pad 12 and the measuring pad 13 is inhibited.

During inspection of the semiconductor chip 10, probe needles (not depicted) that are metal contacts of inspection equipment are in contact with the gate pad 12 and the measuring pad 13 with the semiconductor chip 10 being in a same state as before assembly of the semiconductor module 30 (refer to FIG. 4). In the inspection of the semiconductor chip 10 using the gate pad 12 and the measuring pad 13, for example, the resistance value of the built-in resistance Rg2 due to the gate resistor 15 may be measured. The measuring pad 13 is not used in the product (the semiconductor module 30) and thus, may be covered by an insulator after the inspection of the semiconductor chip 10, however, by leaving the measuring pad 13 exposed, the number of manufacturing processes may be reduced.

During assembly of the semiconductor module 30 (refer to FIG. 4), first ends of the external-lead wiring 32 (32a, 32b) are bonded to the source pad 11 and the gate pad 12, via the different solder layers 31 (31a, 31b), respectively. Second ends of the external-lead wiring 32 (32a, 32b) are exposed outside of a case (not depicted) of the semiconductor module 30. The external-lead wiring 32 is constituted by wires, terminal pins, etc. The external-lead wiring 32a, 32b has a function of externally leading out potential of the source pad 11 and the gate pad 12, respectively. The external-lead wiring 32a is connected to an external ground potential (lowest potential).

In the openings (first and second openings) 26a, 26b of the passivation film 26, in an entire area of the surface of the source pad 11 and an entire area of the surface of the gate pad 12, a plating film (not depicted) containing, for example, nickel (Ni) having high solder wettability may be provided. Wet spreading (solder wettability) of the solder layers 31 during solder reflow is enhanced by the plating film. The solder layers (first and second metal contact layers) 31a, 31b are provided on the surface of the source pad 11 and the surface of the gate pad 12, respectively, via the openings 26a, 26b of the passivation film 26. The respective surfaces of the solder layers 31 are positioned higher than the surface of the passivation film 26. The solder layers 31a, 31b extend onto the surface of the passivation film 26.

During soldering of the external-lead wiring 32b to the gate pad 12, in the semiconductor chip 10 (hereinafter, the conforming chip 10a) free of short-circuit between the gate pad 12 and the measuring pad 13, the solder layers 31a, 31b are apart from each other and terminate on the surface of the passivation film 26 (FIG. 2). In this instance, the surface areas of the solder layers 31a, 31b are substantially the same as the surface areas of the openings 26a, 26b of the passivation film 26, respectively, or are greater than the surface areas of the openings 26a, 26b of the passivation film 26, respectively. External-lead wiring is not bonded to the measuring pad 13. The measuring pad 13 may remain exposed. A portion of the source pad 11 exposed inward from a portion where the opening 26a of the passivation film 26 and the source pad 11 come into contact with each other is defined as an opening surface area of the source pad 11. Similarly, a portion of the gate pad 12 exposed inward from a portion where the opening 26b of the passivation film 26 and the gate pad 12 come into contact is defined as an opening surface area of the gate pad 12. Similarly, a portion of the measuring pad 13 exposed inward from a portion where the opening 26c of the passivation film 26 and the measuring pad 13 come in contact is defined as an opening surface area of the measuring pad 13.

During soldering of the external-lead wiring 32b to the gate pad 12, in the defective chip 10b in which the gate pad 12 and the measuring pad 13 short-circuit, between the gate pad 12 and the measuring pad 13, the solder layer 31b on the gate pad 12 and the solder layer 31a on the source pad 11 are connected by the solder layer 31b that wets and spreads onto the measuring pad 13 from on the gate pad 12. In this instance, the solder layer 31b terminates on the measuring pad 13 (FIG. 3) or also fills the opening 26c of the passivation film 26. The gate pad 12 and the source pad 11 are short-circuited by the solder layer 31b.

The semiconductor module 30 depicted in FIG. 4 has mounted therein the semiconductor chips 10 each having the same structure (refer to FIGS. 1 to 3); the semiconductor module 30 is a MOSFET module in which the MOSFETs 20 fabricated (manufactured) in the semiconductor chips 10 are connected in parallel to one another. The gate pads 12 of the semiconductor chips 10 are connected in parallel to one another by the external-lead wiring 32 (refer to FIGS. 2 and 3) and are electrically connected to protective grounding (PG) 33 of the semiconductor module 30, via the chip resistance Rg4 of the semiconductor chip 10. In each of the semiconductor chips 10, the parasitic resistance Rg1 due to the gate electrodes 56 and the built-in resistance Rg2 due to the gate resistor 15 are connected in series between the PG 33 and the gate electrodes 56 of the MOSFET 20.

Among the semiconductor chips 10, variation of the parasitic resistance Rg1 due to the gate electrodes 56 is large. Thus, the resistance value of the built-in resistance Rg2 is adjusted by the gate resistor 15 added to the semiconductor chip 10, whereby the resistance value of the gate resistance Rg3 of the semiconductor chip 10 determined by the resistance value of the built-in resistance Rg2 is controlled. Based on the resistance value of the built-in resistance Rg2 due to the gate resistor 15 and measured using the measuring pad 13, the semiconductor chips 10 are sorted and only the semiconductor chips 10 in which the resistance value of the gate resistance Rg3 is within a predetermined range are mounted in the semiconductor module 30. As a result, switching variation of the semiconductor chips 10 that are connected in parallel in the semiconductor module 30 may be reduced.

During assembly of the semiconductor module 30, the measuring pad 13 of each of the semiconductor chips 10 is in an exposed state. During soldering of the external-lead wiring 32b to the gate pad 12, when the solder material wets and spreads on the measuring pad 13 from on the gate pad 12, and the gate pad 12 and the measuring pad 13 are connected via the solder layers 31, the gate pad 12 and the source pad 11 are short-circuited by the solder layers 31 (FIG. 3). Thus, even when the MOSFETs 20 fabricated in the semiconductor chips 10 are connected in parallel, a defective chip 10b in which the gate pad 12 and the measuring pad 13 have the same potential may be detected.

Operation of the semiconductor device 20-1 mounted in the semiconductor module 30 is described. When voltage that is positive with respect to the source electrode 59 is applied to the drain electrode 18 and voltage that is at least equal to a gate threshold voltage is applied to the gate electrodes 56, a channel (n-type inversion layer) is formed along sidewalls of the trenches 54 in portions of the p-type base region 51 between the n⁺-type source regions 52 and the n-type current spreading regions 58. As a result, a drift current (main current) flows from the n⁺-type drain region 27, along the n⁻-type drift region 21, the n-type current spreading regions 58, and the channel, to the n⁺-type source regions 52 and the MOSFET 20 turns on.

On the other hand, with voltage that is positive with respect to the source electrode 59 is applied to the drain electrode 18 and voltage that is lower than the gate threshold voltage is applied to the gate electrodes 56, pn junctions (main junctions) between the p-type base region 51, the p⁺-type regions 57, the n-type current spreading regions 58, and the n⁻-type drift region 21 are reverse biased and thus, the MOSFET 20 maintains an off state. A depletion layer spreads in the active-region operating region in a vertical direction (toward the source electrode 59 and the drain electrode 18) from the pn junctions; and a depletion layer spreads in a horizontal direction from the active-region operating region to the active-region non-operating region and the edge terminating region 2, thereby ensuring a predetermined breakdown voltage.

During an interval when the MOSFET 20 transitions from the on-state to the off-state, parasitic pn junction diodes (body diodes) formed by pn junctions between the p-type base region 51, the p⁺-type regions 57, the p⁺-type outer peripheral region 22, the n-type current spreading regions 58, and the n⁻-type drift region 21 conduct in the forward direction, carriers (holes and electrons) are injected into and accumulate in the n⁻-type drift region 21. From this state, when the MOSFET 20 turns off (reverse recovery of the body diodes), holes in the n⁻-type drift region 21 in the edge terminating region 2 become displacement current, flow into the p⁺-type outer peripheral region 22 and are discharged to the source electrode 59, whereby the MOSFET 20 enters the off-state.

The distance between the gate pad 12 and the measuring pad 13 is relatively short and thus, raising of the potential of the field oxide film 24 by displacement current that flows during the interval when the MOSFET 20 transitions from the on-state to the off-state may be suppressed. Further, only the semiconductor chips 10 in which the resistance value of the gate resistance Rg3 is within a predetermined range are mounted in the semiconductor module 30 and switching variation of the semiconductor chips 10 that are connected in parallel in the semiconductor module 30 may be reduced. Further, of the semiconductor chips 10 mounted in the semiconductor module 30, the defective chips 10b in which the gate pad 12 and the measuring pad 13 are short-circuited may be detected.

As described, according to the first embodiment, a portion of the source pad intervenes between the gate pad and the measuring pad. When the gate pad and the measuring pad short-circuit due to solder material that flows out from on the gate pad during soldering of the external-lead wiring to the gate pad in the assembly process of the semiconductor module, the gate pad and the source pad short-circuit. Thus, of the semiconductor chips mounted in parallel in the semiconductor module, a defective chip in which the gate pad and the measuring pad have the same potential may be detected. Therefore, shipping of a product (semiconductor module) in which a defective chip is mounted may be prevented.

Further, according to the first embodiment, short-circuit of the gate pad and the measuring pad may be detected assuredly and thus, the gate pad and the measuring pad may be disposed close to each other. As a result, increases in the overall MOSFET gate resistance value and destruction tolerance against displacement current during switching of the MOSFET may be enhanced.

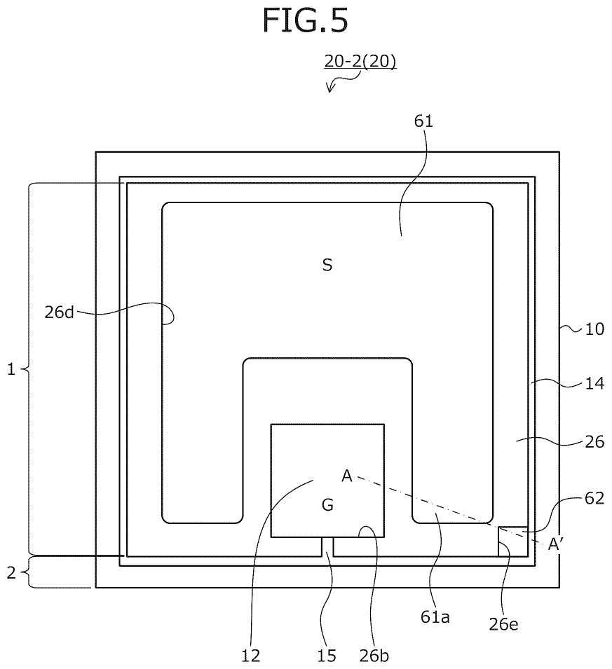

A semiconductor device and a semiconductor module according to a second embodiment solving the problems above is described. FIG. 5 is a plan view depicting an example of a layout when a semiconductor chip mounted on the semiconductor module according to the second embodiment is viewed from a front side thereof. A structure of the semiconductor module according to the second embodiment is a same as the structure depicted in FIG. 4 when reference numeral 13 is replaced with reference numeral 62. A semiconductor device 20-2 according to the second embodiment differs from the semiconductor device 20-1 according to the first embodiment (refer to FIGS. 1 to 3) in that a source pad 61 has a different shape in a plan view and a measuring pad 62 is disposed.

In the second embodiment, a portion of the source electrode 59 (refer to FIGS. 2 and 3) of the MOSFET 20 exposed in an opening 26d of the passivation film 26 functions as the source pad 61. The source pad 61, the gate pad 12, and the measuring pad 62 are exposed, respectively, in different openings 26d, 26b, 26e of the passivation film 26 and are disposed apart from one another. The source pad 61 has a substantially rectangular shape in which a portion is recessed so as to border the periphery of the gate pad 12 in a plan view, the source pad 61 bordering three sides of the periphery of the gate pad 12. A portion 61a of the source pad 61 intervenes between the gate pad 12 and the measuring pad 62.

The gate pad 12 is disposed near the outer periphery of the active region 1, near a center of one predetermined side of the outer periphery of the active region 1. Of the four corner portions (vertices) of the active region 1, the measuring pad 62 is disposed in a corner close to the gate pad 12. The source pad 61 is disposed so as to overlap, as much as possible, a linear path in a direction from the gate pad 12 to the measuring pad 62 when viewed from the front surface of the semiconductor chip 10. Other than the shape of the source pad 61 in a plan view, configuration thereof is the same as the configuration of the source pad 11 (also including the structure of the MOSFET 20) of the first embodiment. Other than arrangement of the measuring pad 62, configuration thereof is the same as the configuration of the measuring pad 13 of the first embodiment.

Even when the distance between the gate pad 12 and the measuring pad 62 is sufficiently wide, short-circuit of the gate pad 12 and the measuring pad 13 due to adhesion of conductive foreign matter may occur (not depicted). Even when the gate pad 12 and the measuring pad 13 short-circuit due to adhesion of conductive foreign matter, between the gate pad 12 and the measuring pad 13, short-circuit of the gate pad 12 and the source pad 11 may be induced by the adhered matter. Thus, even in a configuration in which the gate pad 12 and the measuring pad 62 are separated by a significant distance, the defective chips 10b in which the gate pad 12 and the measuring pad 62 are short-circuited may be detected.

As described, according to the second embodiment, even in a configuration in which the gate pad and the measuring pad are separated by a significant distance, while tolerance against destruction by displacement current during switching of the MOSFET slightly decreases, effects similar to those of the first embodiment may be obtained.

In the foregoing, the present disclosure is not limited to the embodiments above and various modifications within a range not departing from the spirit of the disclosure are possible. For example, as a bonding material used to bond external-lead wiring to the source pad and the gate pad, instead of a solder material, a metal sintering material such as a silver (Ag) nanoparticle sinter may be used. Further, instead of the trench gate structure, a planar gate structure may be provided. At the front surface of the semiconductor chip, an electrode pad other than the source pad, the gate pad, and the measuring pad may be provided. The semiconductor material of the semiconductor chip may be silicon (Si).

The semiconductor device and the semiconductor module according to the present disclosure achieve an effect in that shipping of a defective chip may be prevented.

As described, the semiconductor device and the semiconductor module according to the present disclosure are useful for power semiconductor modules used in power converting equipment, power source devices of various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate having a main surface;
a semiconductor device element provided in the semiconductor substrate at the main surface thereof, the semiconductor device element having an insulated gate with a three-layer structure formed by:
a metal film that constitutes a gate electrode,
an oxide film, and
a portion of the semiconductor substrate;
a main electrode pad provided at the main surface of the semiconductor substrate for energizing the semiconductor device element;
a first external member bonded to the main electrode pad by a metal;
a gate pad provided at the main surface of the semiconductor substrate via an insulating film;
a gate finger provided at the main surface of the semiconductor substrate via the insulating film, the gate finger being electrically connected to the gate electrode;
a gate resistor provided at the main surface of the semiconductor substrate via the insulating film, the gate resistor electrically connecting the gate pad and the gate finger; and
a measuring pad for measuring a resistance value of the gate resistor, the measuring pad being provided at the main surface of the semiconductor substrate via the insulating film and being electrically connected to the gate finger, wherein
in a plan view of the semiconductor device, a portion of the main electrode pad is between the gate pad and the measuring pad.

2. The semiconductor device according to claim 1, further comprising a second external member bonded by another metal to the gate pad.

3. The semiconductor device according to claim 1, further comprising a first metal bonding layer connecting the main electrode pad and the first external member and having a surface area larger than an opening surface area of the main electrode pad in the plan view.

4. The semiconductor device according to claim 1, further comprising:
a passivation film covering the main surface of the semiconductor substrate and having a first opening through which the main electrode pad exposes; and
a first metal bonding layer bonding the main electrode pad and the first external member, the first metal bonding layer filling the first opening and extending onto a surface of the passivation film.

5. The semiconductor device according to claim 2, further comprising a second metal bonding layer bonding the gate pad and the second external member and having a surface area larger than an opening surface area of the gate pad in the plan view.

6. The semiconductor device according to claim 2, further comprising:
a passivation film covering the main surface of the semiconductor substrate and having a second opening through which the gate pad exposes; and
a second metal bonding layer bonding the gate pad and the second external member, the second metal bonding layer filling the second opening and extending onto a surface of the passivation film.

7. The semiconductor device according to claim 3, wherein the first metal bonding layer is formed of a solder material or a metal sintering material.

8. The semiconductor device according to claim 5, wherein the second metal bonding layer is formed of a solder material or a metal sintering material.

9. The semiconductor device according to claim 3, wherein
the first metal bonding layer is formed of a solder material, and
the main electrode pad is bonded to the first metal bonding layer via a plating film.

10. The semiconductor device according to claim 5, wherein
the second metal bonding layer is formed of a solder material, and
the gate pad is bonded to the second metal bonding layer via a plating film.

11. A semiconductor module comprising a plurality of the semiconductor devices of claim 1, wherein
the plurality of semiconductor device elements of the plurality of the semiconductor devices are connected in parallel, and
the plurality of first external members of the plurality of the semiconductor devices are bonded by the metal to the main electrode pads of the plurality of the semiconductor devices.
